(19) United States
(12) Patent Application Publication
(10) Pub. No.: US 2017/0117282 A1
(43) Pub. Date: Apr. 27, 2017

(54) DRAM Capacitors and Methods for Forming the Same

(71) Applicant: Intermolecular, Inc., San Jose, CA (US)

(72) Inventors: Monica S. Mathur, Dublin, CA (US); Randall Higuchi, San Jose, CA (US); Thong Quang Ngo, San Jose, CA (US); Sandip Niyogi, San Jose, CA (US); Prashant Phatak, San Jose, CA (US)

(73) Assignee: Intermolecular, Inc., San Jose, CA (US)

(21) Appl. No.: 15/334,278

(22) Filed: Oct. 25, 2016

Related U.S. Application Data
(60) Provisional application No. 62/246,409, filed on Oct. 26, 2015.
(60) Provisional application No. 62/259,980, filed on Nov. 25, 2015.

(51) Int. Cl. H01L 27/108; H01L 49/02

(52) U.S. Cl. CPC H01L 27/10852; H01L 27/10814; H01L 28/65; H01L 28/56

(57) ABSTRACT

Embodiments provided herein describe capacitor stacks and methods for forming capacitor stacks. A first electrode is formed above a substrate. A dielectric layer is formed above the first electrode. The dielectric layer includes zirconium. A second electrode is formed above the dielectric layer. At least one of the first electrode and the second electrode includes iridium.

### CROSS-REFERENCE TO RELATED APPLICATIONS

This application claims priority to U.S. Provisional Patent Application No. 62/246,409, filed on Oct. 26, 2015, and U.S. Provisional Patent Application No. 62/259,980, filed on Nov. 25, 2015, each of which is herein incorporated by reference for all purposes.

### TECHNICAL FIELD

The present invention relates to capacitors used in Dynamic Random Access Memory (DRAM) devices. More particularly, this invention relates to DRAM capacitors with improved performance and methods for forming such DRAM capacitors.

### BACKGROUND

Dynamic Random Access Memory (DRAM) devices utilize capacitors to store bits of information within an integrated circuit. The capacitors are formed by placing a dielectric material between two electrodes formed from conductive materials. The ability of such a capacitor to hold electrical charge (i.e., capacitance) is a function of the surface area of the capacitor plates, the distance between the capacitor plates d (i.e. the physical thickness of the dielectric layer), and the relative dielectric constant, or k-value, of the dielectric material.

Aggressive scaling of DRAM cell dimensions, as envisioned in future technologies, requires a dielectric film with a higher dielectric constant and lower leakage current density than current DRAM capacitors, or metal-insulator-metal (MIM) stacks, such as those using titanium nitride (TiN), zirconium oxide (ZrO₂), and/or aluminum oxide (Al₂O₃) (e.g., TiN/ZrO₂/TiN, TiN/ZrO₂/Al₂O₃/ZrO₂/TiN, etc.). Titanium oxide (TiO₂) has been identified as a potential replacement dielectric to achieve a high dielectric constant. However, the dielectric constant of titanium oxide strongly depends on the crystalline phase formed. Anatase titanium oxide typically has a dielectric constant of about 30-40, whereas rutile titanium oxide typically has a dielectric constant of about 90-170, depending on orientation. Another potential issue with the use of titanium oxide in DRAM capacitors is that titanium oxide inherently has a higher leakage current density than, for example, zirconium oxide (ZrO₂).

These issues, combined with the fact that zirconium oxide is already used in such capacitors, indicate that it would be preferable to improve the performance of zirconium oxide-based capacitors to achieve the performance requirements of future technologies.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIGS. 1-5 are simplified cross-sectional views of a substrate with a DRAM capacitor formed thereon according to some embodiments.

FIG. 6 is a graph illustrating the change in equivalent oxide thickness (EOT) of zirconium oxide when formed over different materials as the thickness of the zirconium oxide is increased.

FIGS. 7 and 8 are graphs illustrating the change in leakage current density of zirconium oxide when used with various bottom and top electrodes as the EOT of the zirconium oxide is increased.

FIG. 9 is a simplified cross-sectional view of a DRAM cell according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide Dynamic Random Access Memory (DRAM) device (or cell) capacitors (or metal-insulator-metal (MIM) stacks) with improved (i.e., higher) dielectric constant and reduced equivalent oxide thickness and leakage current density compared to current, conventional stacks and methods for forming such MIM stacks.

In some embodiments, the capacitor stack includes a dielectric (e.g., a dielectric layer) formed between a bottom electrode and a top electrode. The dielectric includes zirconium (e.g., zirconium oxide), and at least one of the electrodes includes iridium. In some embodiments, the dielectric is a multi-layer dielectric that includes a thin layer of titanium oxide (e.g., rutile titanium oxide in some instances) between the remainder of the dielectric (e.g., zirconium oxide, such as tetragonal zirconium oxide) and a iridium-containing electrode (i.e., either the bottom electrode or the top electrode).

For example, in some embodiments, the dielectric includes zirconium oxide and both the bottom electrode and the top electrode include iridium. In some embodiments, the dielectric includes zirconium oxide, one of the electrodes (i.e., either the bottom electrode or the top electrode) includes iridium, and the other electrode includes, for example, titanium nitride. In some embodiments, at least one of the electrodes includes iridium, and the dielectric includes a zirconium oxide sub-layer and thin sub-layer of titanium oxide, with the titanium oxide being formed between the zirconium oxide sub-layer and iridium (i.e., of either electrode).

The use of iridium in the electrode(s) promotes relatively high-k crystalline phases in the dielectrics in contact with the electrodes (e.g., by serving as template layers). That is, iridium promotes tetragonal zirconium oxide (t-ZrO₂) with a dielectric constant of about 47. This effect may be enhanced with/during an annealing process (e.g., 400-600° C. in argon and/or nitrogen gas). When the thin layer of titanium oxide is used between one of the electrodes and the dielectric, the titanium oxide may reduce defects at the interface between the two materials and/or change the dielectric (e.g., zirconium oxide).

In some embodiments, the capacitor stack includes a multi-layer dielectric formed between a bottom electrode and a top electrode, with a first layer in the dielectric including a high dielectric constant (high-k) material and a second layer including a material with a lower leakage current density than the high-k material.

In some embodiments, the first layer in the dielectric includes titanium (e.g., titanium oxide), the second layer in the dielectric includes zirconium (e.g., zirconium oxide), and the bottom and top electrodes each include iridium. For example, the first dielectric layer may include rutile titanium oxide, the second dielectric layer may include of tetragonal zirconium oxide, and the electrodes may be made of iridium or iridium oxide. In some embodiments, the titanium oxide is not rutile titanium oxide when it is in contact with iridium (as opposed to iridium oxide) and/or when it is relatively thin (e.g., about 0.2 nanometers (nm)).

In some embodiments, the bottom electrode is formed above a substrate and includes (e.g., is made of) iridium oxide. The first dielectric layer is formed above the bottom electrode and includes titanium oxide. The second dielectric layer is formed above the first dielectric layer and includes zirconium oxide. The top electrode is formed above the second dielectric layer and includes iridium.

In some embodiments, the bottom electrode is formed above a substrate and includes (e.g., is made of) iridium. The first dielectric layer is formed above the bottom electrode and includes zirconium oxide. The second dielectric layer is formed above the first dielectric layer and includes titanium oxide. The top electrode is formed above the second dielectric layer and includes iridium oxide.

The use of iridium and iridium oxide in the electrodes promote relatively high-k crystalline phases in the dielectrics in contact with the electrodes (e.g., by serving as template layers). That is, iridium oxide promotes rutile titanium oxide (r-TiO₂) with a dielectric constant between about 90 and about 170, and iridium promotes tetragonal zirconium oxide (t-ZrO₂) with a dielectric constant of about 47. This effect may be enhanced with/during an annealing process (e.g., 400-600° C. in argon and/or nitrogen gas).

The resulting capacitor(s) may exhibit improve dielectric constant/decreased equivalent oxide thickness and/or decreased leakage current density and may allow for the continued use of zirconium oxide-based dielectrics in future technology nodes.

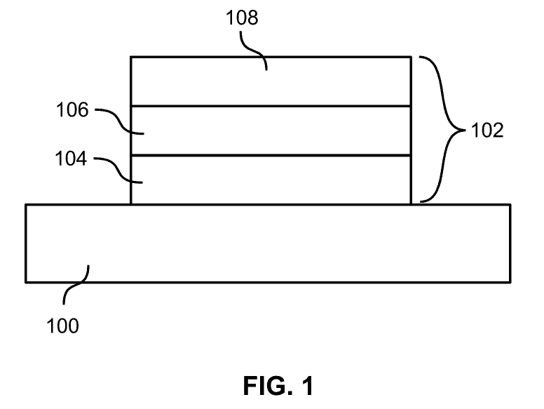

FIG. 1 is a simplified illustration of a substrate 100 with a DRAM capacitor 102 formed thereon according to some embodiments. The substrate 100 may include, for example, a relatively thick layer of a thermal oxide (e.g., silicon oxide) formed over a semiconductor substrate (e.g., a silicon substrate). In some embodiments, the DRAM capacitor 102 includes a bottom (or first) electrode 104, a dielectric layer 106, and a top (or second) electrode 108. Although the DRAM capacitor 102 is shown in FIG. 1 as a simple “stack” configuration, the DRAM capacitor 102 may be shaped/formed into more complex structures with, for example, various columns and/or pillars extending from the substrate 100, as will be appreciated by one skilled in the art.

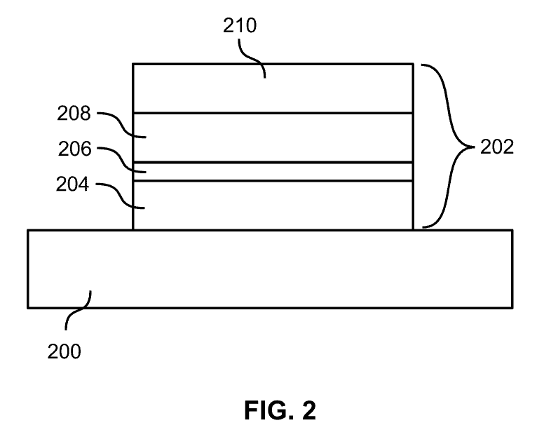

The various components (or layers) 104-108 of the DRAM capacitor 102 shown in FIG. 1, as well as the component/layers of the capacitors described below with respect to FIGS. 2-5, may be sequentially formed above the substrate 100 using any suitable deposition technique, such as atomic layer deposition (ALD), chemical vapor deposition (CVD), plasma-enhanced CVD (PECVD), physical vapor deposition (PVD), or a combination thereof. In some embodiments, components/layers that are shown in the figures as being adjacent are formed directly on and/or in contact with one another, while in other embodiments, other, intervening components/layers may be included.

Still referring to FIG. 1, in some embodiments, the bottom electrode 104 includes (e.g., is made of) iridium, the dielectric layer 106 includes (e.g., is made of) zirconium oxide, and the top electrode 108 includes (e.g., is made of) iridium. In some embodiments, the bottom electrode 104 includes (e.g., is made of) iridium, the dielectric layer 106 includes (i.e., is made of) zirconium oxide, and the top electrode 108 includes (e.g., is made of) titanium nitride. In some embodiments, the bottom electrode 104 includes (e.g., is made of) titanium nitride, the dielectric layer 106 includes (i.e., is made of) zirconium oxide, and the top electrode 108 includes (e.g., is made of) iridium. The bottom electrode 104 may have a thickness of, for example, between about 0.2 nm and about 10 nm. The dielectric layer 106 may have a thickness of, for example, between about 3 nm and about 8 nm. The top electrode 108 may have a thickness of, for example, between about 0.2 nm and about 10 nm.

Referring now to FIG. 2, a substrate 200 is shown with a DRAM capacitor 202 formed thereon according to some embodiments. The DRAM capacitor 202 includes a bottom electrode 204, a first (or lower) dielectric layer 206, a second (or upper) dielectric layer 208, and a top electrode 210. The substrate 200, the electrodes 204 and 210, and the second dielectric layer 208 may be similar to the respective substrate 100, electrodes 104 and 108, and the dielectric layer 106 described above with respect to FIG. 1. The first dielectric layer 206 is formed between (e.g., and may be in direct contact with) the bottom electrode 204 and the second dielectric layer 208. In some embodiments, the first dielectric layer 206 includes (e.g., is made of) titanium oxide and may have a thickness of, for example, between about 0.1 nm and about 2 nm (or between about 0 nm and about 2 nm). The first dielectric layer 206, and other similar, thin layers, may be referred to as a “flash” layer.

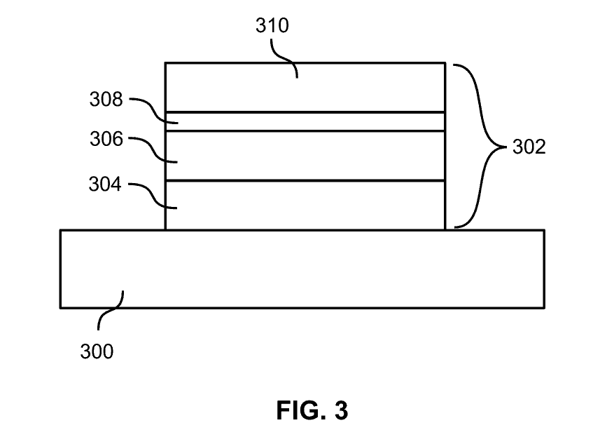

Referring now to FIG. 3, a substrate 300 is shown with a DRAM capacitor 302 formed thereon according to some embodiments. The DRAM capacitor 302 includes a bottom electrode 304, a first (or lower) dielectric layer 306, a second (or upper) dielectric layer 308, and a top electrode 310. The substrate 300, the electrodes 304 and 310, and the first dielectric layer 306 may be similar to the respective substrates 100 and 200, electrodes 104, 108, 204, and 210, and dielectric layers 106 and 208 described above with respect to FIGS. 1 and 2. The second dielectric layer 308 is formed between (e.g., and may be in direct contact with) the first dielectric layer 306 and the top electrode 310. In some embodiments, the second dielectric layer 308 includes (e.g., is made of) titanium oxide and may have a thickness of, for example, between about 0.1 nm and about 2 nm (or between about 0 nm and about 2 nm) (e.g., a flash layer).

In other words, the DRAM capacitor 302 of FIG. 3 may include components/layers that are similar to the DRAM capacitor 202 of FIG. 2. However, as described above, the relative positions of the relatively thin titanium oxide layer (i.e., the first dielectric layer 206 of FIG. 2 and the second dielectric layer 308 of FIG. 3) and the thicker zirconium oxide layer are reversed.

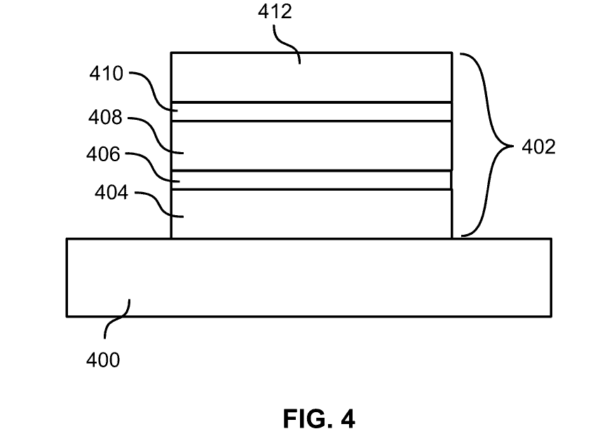

Referring now to FIG. 4, a substrate 400 is shown with a DRAM capacitor 402 formed thereon according to some embodiments. The DRAM capacitor 402 includes a bottom electrode 404, a first (or lower) dielectric layer 406, a second (or middle) dielectric layer 408, a third (or upper dielectric) layer 410, and a top electrode 410. The substrate 400, electrodes 404 and 412, and the second dielectric layer 306 may be similar to the respective substrates 100, 200, and 300, electrodes 104, 108, 204, 210, 304, and 310 and the dielectric layers 106, 208, and 306 described above with respect to FIGS. 1-3. The first dielectric layer 406 is formed between (e.g., and may be in direct contact with) the bottom electrode 404 and the second dielectric layer 408, and the third dielectric layer 410 is formed between (e.g., and may be in direct contact with) the second dielectric layer 408 and the top electrode 412. In some embodiments, the first dielectric layer 406 and the third dielectric layer 410 include (e.g., are made of) titanium oxide. Each of the first dielectric layer 406 and the third dielectric layer 410 may have a thickness of, for example, between about 0.1 nm and about 8 nm (or between about 0 nm and about 2 nm) (e.g., flash layers).

In other words, the DRAM capacitor 402 of FIG. 4 may include components/layers that are similar to the DRAM capacitors 202 of FIG. 2 and 302 of FIG. 3. However, as described above, the DRAM capacitor 402 of FIG. 4 may include two relatively thin titanium oxide layers on opposing sides of the relative thick middle oxide layer.

In some embodiments, at least one dopant is added to the material used to form the dielectric layer(s) of the DRAM capacitors described above. The dopant used may include at least one of aluminum, cerium, cobalt, erbium, gallium, gadolinium, germanium, hafnium, indium, lanthanum, lutetium, magnesium, manganese, neodymium, praseodymium, scandium, silicon, tin, strontium, yttrium, or a combination thereof. The dopant(s) may be added using, for example, during the deposition of the particular layer/component (e.g., during an ALD process) or after the formation of the particular layer/component (e.g., via ion implantation).

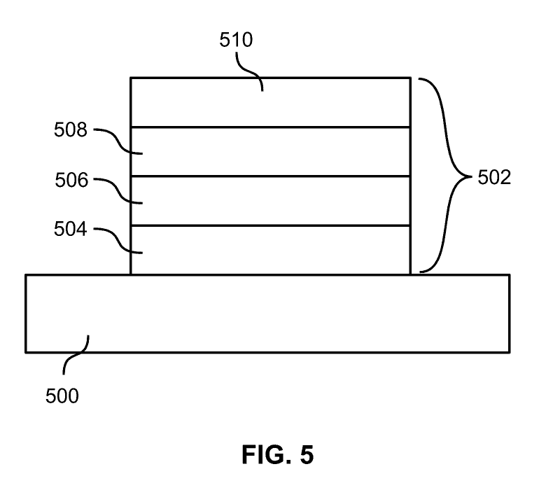

Referring now to FIG. 5, a substrate 500 is shown with a DRAM capacitor 502 formed thereon according to some embodiments. The substrate 500 may include, for example, a relatively thick layer of a thermal oxide (e.g., silicon oxide) formed over a semiconductor substrate (e.g., a silicon substrate). The DRAM capacitor 502 includes a bottom electrode 504, a first (or lower) dielectric layer 506, a second (or upper) dielectric layer 508, and a top electrode 510.

In some embodiments, the bottom electrode 504 includes iridium oxide, the lower dielectric layer 506 includes titanium oxide, the upper dielectric layer 508 includes zirconium oxide, and the top electrode 510 includes iridium. For example, the bottom electrode 504 may include (e.g., be made of) iridium oxide and have a thickness of, for example, between about 0.2 nm and about 10 nm. The lower dielectric layer 506 may include (e.g., be made of) titanium oxide and have a thickness of, for example, between about 0.2 nm and about 8 nm. The upper dielectric layer 508 may include (e.g., be made of) zirconium oxide and have a thickness of, for example, between about 0.1 nm and about 6 nm. The top electrode 510 may include (e.g., be made of) iridium and have a thickness of, for example, between about 0.2 nm and about 10 nm.

In some embodiments, the bottom electrode 504 includes iridium, the lower dielectric layer 506 includes zirconium oxide, the upper dielectric layer 508 includes titanium oxide, and the top electrode 510 includes iridium oxide. For example, the bottom electrode 504 may include (e.g., be made of) iridium and have a thickness of, for example, between about 0.2 nm and about 10 nm. The lower dielectric layer 506 may include (e.g., be made of) zirconium oxide and have a thickness of, for example, between about 0.1 nm and about 6 nm. The upper dielectric layer 508 may include (e.g., be made of) titanium oxide and have a thickness of, for example, between about 0.5 nm and about 8 nm. The top electrode 510 may include (e.g., be made of) iridium oxide and have a thickness of, for example, between about 0.2 nm and about 10 nm.

In some embodiments, at least one dopant is added to the material used to form the lower dielectric layer 506 and/or the upper dielectric layer 508. The dopant used may include at least one of aluminum, cerium, cobalt, erbium, gallium, gadolinium, germanium, hafnium, indium, lanthanum, lutetium, magnesium, manganese, neodymium, praseodymium, scandium, silicon, tin, strontium, yttrium, or a combination thereof. The dopant(s) may be added using, for example, during the deposition of the particular layer/component (e.g., during an ALD process) or after the formation of the particular layer/component (e.g., via ion implantation).

As such, embodiments described herein provide DRAM device (or cell) capacitors (or metal-insulator-metal (MIM) stacks), as well as methods for forming such capacitor (or stacks). Exemplary stacks may include, but not are not limited to, the following: Ir/TiOₓ (0-2 nm)/ZrO₂/TiN; Ir/ZrO₂/TiN; Ir/TiOₓ (0.1-2 nm)/ZrO₂/TiN; TiN/ZrO₂/TiOₓ (0-2 nm)/Ir; TiN/ZrO₂/Ir; TiN/ZrO₂/TiOₓ (0.1-2 nm)/Ir; Ir/TiOₓ (0-2 nm)/ZrO₂/TiOₓ (0-2 nm)/IrOₓ (x=0-2); Ir/ZrO₂/Ir; Ir/TiOₓ (0.1-2 nm)/ZrO₂/Ir; Ir/ZrO₂/IrOₓ (x=0.1-2); Ir/TiOₓ (0.1-2 nm)/ZrO₂/IrOₓ (x=0-2); Ir/TiOₓ (0.1-2 nm)/ZrO₂/TiOₓ (0.1-2 nm)/Ir; Ir/TiOₓ (0.1-2 nm)/ZrO₂/TiOₓ (0.1-2 nm)/IrOₓ (x=0-2); Ir/ZrO₂(0.5-8 nm)/TiOₓ (0.5-8 nm)/IrO₂; IrO₂/TiOₓ (0.5-8 nm)/ZrO₂ (0.5-8 nm)/Ir; Ir/TiOₓ (0.1-2 nm)/ZrO₂ (0.5-8 nm)/TiOₓ (0.5-8 nm)/IrO₂.

Experimental data suggests that DRAM capacitors formed as described above exhibit improved performance with respect to, for example, equivalent oxide thickness (EOT) and leakage current density when compared to current DRAM capacitors, or metal-insulator-metal (MIM) stacks, such as TiN/ZrO₂/TiN, TiN/ZrO₂/Al₂O₃/ZrO₂/TiN, etc. Additionally, the DRAM capacitors described above may allow for the continued use of zirconium oxide-based dielectrics, as well as perhaps titanium nitride electrodes, in DRAM capacitors while still meeting the performance requirements of future technologies.

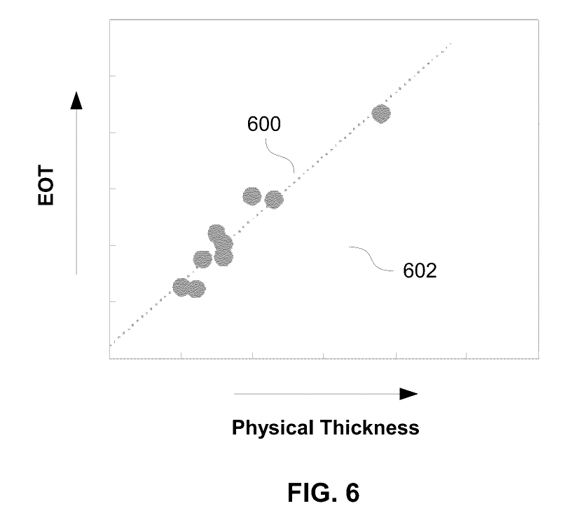

FIG. 6 is a graph illustrating the change in EOT of zirconium oxide when formed over titanium nitride and iridium (e.g., titanium nitride and iridium bottom electrodes), as the (physical) thickness of the zirconium oxide is increased. In particular, line (and/or data points) 600 corresponds to zirconium oxide formed over titanium nitride, and line 602 correspond to zirconium oxide formed over iridium. As shown, for both titanium nitride and iridium, the EOT increases as the thickness of the zirconium oxide increases. However, at all thicknesses shown, the EOT of the zirconium oxide is less when formed over iridium when compared to being formed over titanium nitride, and the EOT increases less rapidly as the thickness of the zirconium oxide increases (i.e., the slope of line 602 is less than that of line 600). This improvement in EOT may be the result of the increased dielectric constant (e.g., about 43%) of the zirconium oxide (e.g., due to a tetragonal phase) when formed over the iridium.

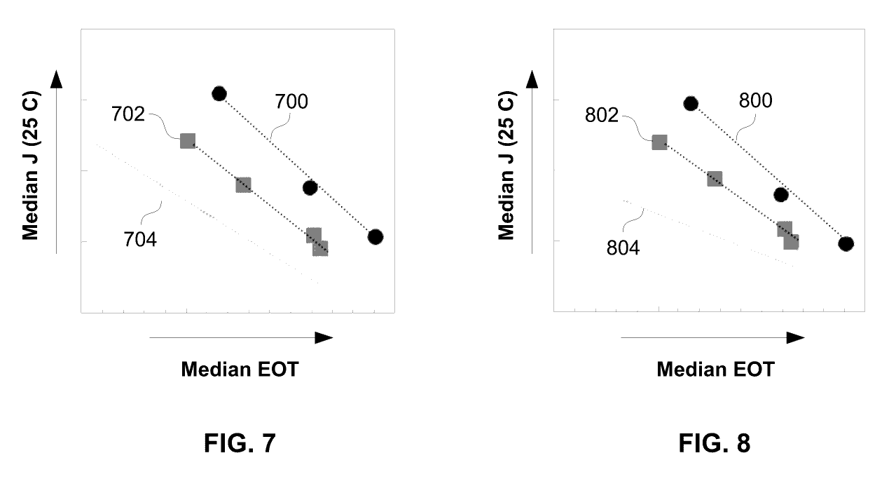

FIGS. 7 and 8 are graphs illustrating the change in leakage current density of zirconium oxide when used with various bottom and top electrodes, at 25° C. and different voltages, respectively, as the EOT of the zirconium oxide is increased. In particular, line (or data points) 700 in FIG. 7 and line 800 in FIG. 8 correspond to a stack with titanium nitride top and bottom electrodes and a zirconium oxide dielectric layer formed between. Line 702 in FIG. 7 and line 802 in FIG. 8 correspond to a stack with an iridium bottom electrode, a zirconium oxide dielectric layer, and a titanium nitride top electrode, with a titanium oxide flash layer formed between the bottom electrode and the dielectric layer. Line 704 in FIG. 7 and line 804 in FIG. 8 correspond to a stack with iridium top and bottom electrodes and a zirconium oxide dielectric layer formed between, along with a titanium oxide flash layer formed between the bottom electrode and the dielectric layer. As is shown in both FIG. 7 and FIG. 8, the leakage current density of the zirconium oxide in all three stacks decreases as the EOT of the zirconium oxide is increased. However, the leakage current density for the zirconium oxide in the stack having an iridium bottom electrode (lines 702 and 802) is lower than that of the zirconium oxide in the stack having titanium nitride top and bottom electrodes (lines 700 and 800). Moreover, the leakage current density for the zirconium oxide is further decreased when used in the stack with iridium bottom and top electrodes (lines 704 and 804).

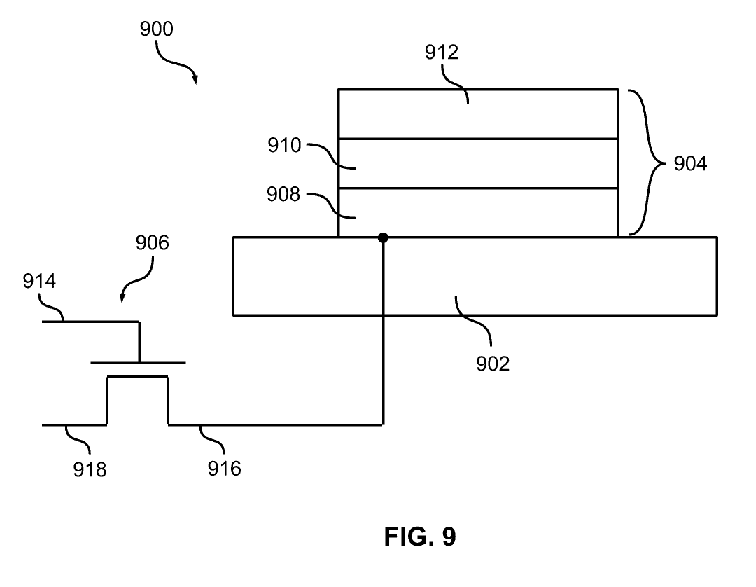

FIG. 9 is a simplified schematic illustration of a DRAM cell 900 according to some embodiments. The DRAM cell 900 includes a substrate 902, with a DRAM capacitor 904 formed thereon, and a DRAM transistor 906.

Although the DRAM capacitor 904 is shown as including a bottom (or first) electrode 908, a (single) dielectric layer 910, and a top (or second) electrode 912, it should be understood that the DRAM capacitor 904 (as well as the substrate 902) may be similar to those described above with reference to FIGS. 1-5 (e.g., the dielectric layer 910 may include/be made of multiple layers).

Although not shown in detail, in some embodiments, the DRAM transistor 906 is a metal-oxide-semiconductor field effect transistor (MOSFET) and includes a gate 914, a source 916, and a drain 918. The gate 916 may be electrically connected to a word line, and one of the source 916 and the drain 918 may be electrically connected to bit line. The other of the source 916 and the drain 918 may be electrically connected to the bottom (or storage) electrode 908 of the DRAM capacitor 904. The DRAM transistor 906 may be turned “on” by an active level of the word line to read or write data from or to the DRAM capacitor 904 via the bit line, as is commonly understood in the art.

Thus, in some embodiments, capacitor stacks, and methods for forming capacitor stacks, are provided. A first electrode is formed above a substrate. A dielectric layer is formed above the first electrode. The dielectric layer includes zirconium. A second electrode is formed above the dielectric layer. At least one of the first electrode and the second electrode includes iridium.

Each of the first electrode and the second electrode may include iridium. One of the first electrode and the second electrode may include iridium, and the other of the first electrode and the second electrode may include titanium nitride. The first electrode may include iridium, and the second electrode may include titanium nitride. The first electrode may include titanium nitride, and the second electrode may include iridium.

A second dielectric layer may be formed above the first electrode. The second dielectric layer may include titanium oxide, and the second electrode may be formed above the second dielectric layer. The first electrode may include iridium, and the second dielectric layer may be formed between the first electrode and the dielectric layer. The second electrode may include iridium, and the second dielectric layer may be formed between the dielectric layer and the second electrode.

The dielectric layer may further include a dopant. The dopant may include at least one of aluminum, cerium, cobalt, erbium, gallium, gadolinium, germanium, hafnium, indium, lanthanum, lutetium, magnesium, manganese, neodymium, praseodymium, scandium, silicon, tin, strontium, yttrium, or a combination thereof. At least one of the first electrode and the second electrode may consist of iridium.

In some embodiments, capacitor stacks, and methods for forming capacitor stacks, are provided. A first electrode is formed above a substrate. A dielectric layer is formed above the first electrode. The dielectric layer includes zirconium. A second electrode is formed above the dielectric layer. At least one of the first electrode and the second electrode consists of iridium.

Each of the first electrode and the second electrode may consist of iridium. One of the first electrode and the second electrode may consist of iridium, and the other of the first electrode and the second electrode may consist of titanium nitride. The dielectric layer may be formed directly on the first electrode, and the second electrode may be formed directly on the dielectric layer. The dielectric layer may include a first sub-layer and a second sub-layer. The first sub-layer may include zirconium oxide, and the second sub-layer may include titanium oxide.

In some embodiments, capacitor stacks, and methods for forming capacitor stacks, are provided. A first electrode is formed above a substrate. The first electrode includes iridium. A first dielectric layer is formed above the first electrode. The first dielectric layer includes titanium. A second dielectric layer is formed above the first electrode. The second dielectric layer includes zirconium. A second electrode is formed above the first dielectric layer and the second dielectric layer. The second electrode includes iridium.

The first dielectric layer may include titanium oxide. The second dielectric layer may include zirconium oxide. The first electrode may include iridium oxide, and the second dielectric layer may be formed above the first electrode and the first dielectric layer. The first dielectric layer may be formed directly on the first electrode, the second dielectric layer may be formed directly on the first dielectric layer, and the second electrode may be formed directly on the second dielectric layer.

The second electrode may include iridium oxide, and the first dielectric layer may be formed above the first electrode and the second dielectric layer. The second dielectric layer may be formed directly on the first electrode, the first dielectric layer may be formed directly on the second dielectric layer, and the second electrode may be formed directly on the first dielectric layer.

At least one of the first dielectric layer and the second dielectric layer may further include a dopant. The dopant may include at least one of aluminum, cerium, cobalt, erbium, gallium, gadolinium, germanium, hafnium, indium, lanthanum, lutetium, magnesium, manganese, neodymium, praseodymium, scandium, silicon, tin, strontium, yttrium, or a combination thereof.

Each of the first electrode and the second electrode may have a thickness between about 0.2 nm and about 10 nm, the first dielectric layer may have a thickness between about 0.2 nm and about 8 nm, and the second dielectric layer may have a thickness between about 0.1 nm and about 6 nm. The first electrode, the first dielectric layer, the second dielectric layer, and the second electrode may be formed using ALD.

In some embodiments, capacitor stacks, and methods for forming capacitor stacks, are provided. A first electrode is formed above a substrate. A second electrode is formed above the substrate. One of the first electrode and the second electrode is positioned between the other of the first electrode and the second electrode and the substrate. A first dielectric layer is formed between the first electrode and the second electrode. The first dielectric layer includes titanium oxide. A second dielectric layer is formed between the first electrode and the second electrode. The second dielectric layer includes zirconium oxide. One of the first electrode and the second electrode is in contact with the first dielectric layer and not the second dielectric layer and comprises of iridium oxide, and the other of the first electrode and the second electrode is in contact with the second dielectric layer and not the first dielectric layer and comprises iridium.

The one of the first electrode and the second electrode in contact with the first dielectric layer and not the second dielectric layer may consist of iridium oxide, and the other of the first electrode and the second electrode in contact with the second dielectric layer and not the first dielectric layer may consist of iridium.

The first dielectric layer may be formed directly on the first electrode, the second dielectric layer may be formed directly on the first dielectric layer, and the second electrode may be formed directly on the second dielectric layer.

At least one of the first dielectric layer and the second dielectric layer may further include a dopant. The dopant may include at least one of aluminum, cerium, cobalt, erbium, gallium, gadolinium, germanium, hafnium, indium, lanthanum, lutetium, magnesium, manganese, neodymium, praseodymium, scandium, silicon, tin, strontium, yttrium, or a combination thereof.

Each of the first electrode and the second electrode may have a thickness between about 0.2 nm and about 10 nm, the first dielectric layer may have a thickness between about 0.2 nm and about 8 nm, and the second dielectric layer may have a thickness between about 0.1 nm and about 6 nm.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a capacitor stack, the method comprising:
forming a first electrode above a substrate;
forming a dielectric layer above the first electrode, wherein the dielectric layer comprises zirconium; and
forming a second electrode above the dielectric layer,
wherein at least one of the first electrode and the second electrode comprises iridium.

2. The method of claim 1, wherein each of the first electrode and the second electrode comprises iridium.

3. The method of claim 1, wherein one of the first electrode and the second electrode comprises iridium, and the other of the first electrode and the second electrode comprises titanium nitride.

4. The method of claim 3, wherein the first electrode comprises iridium, and the second electrode comprises titanium nitride.

5. The method of claim 3, wherein the first electrode comprises titanium nitride, and the second electrode comprises iridium.

6. The method of claim 1, further comprising forming a second dielectric layer above the first electrode, wherein the second dielectric layer comprises titanium oxide, and the second electrode is formed above the second dielectric layer.

7. The method of claim 6, wherein the first electrode comprises iridium, and the second dielectric layer is formed between the first electrode and the dielectric layer.

8. The method of claim 6, wherein the second electrode comprises iridium, and the second dielectric layer is formed between the dielectric layer and the second electrode.

9. The method of claim 1, wherein the dielectric layer further comprises a dopant, wherein the dopant comprises at least one of aluminum, cerium, cobalt, erbium, gallium, gadolinium, germanium, hafnium, indium, lanthanum, lutetium, magnesium, manganese, neodymium, praseodymium, scandium, silicon, tin, strontium, yttrium, or a combination thereof.

10. The method of claim 1, wherein at least one of the first electrode and the second electrode consists of iridium.

11. A method for forming a capacitor stack, the method comprising:
forming a first electrode above a substrate;
forming a dielectric layer above the first electrode, wherein the dielectric layer comprises zirconium; and
forming a second electrode above the dielectric layer,
wherein at least one of the first electrode and the second electrode consists of iridium.

12. The method of claim 11, wherein each of the first electrode and the second electrode consists of iridium.

13. The method of claim 11, wherein one of the first electrode and the second electrode consists of iridium, and the other of the first electrode and the second electrode consists of titanium nitride.

14. The method of claim 11, wherein the dielectric layer is formed directly on the first electrode, and the second electrode is formed directly on the dielectric layer.

15. The method of claim 11, wherein the dielectric layer comprises a first sub-layer and a second sub-layer, wherein the first sub-layer comprises zirconium oxide, and the second sub-layer comprises titanium oxide.

16. A method for forming a capacitor stack, the method comprising:
forming a first electrode above a substrate, wherein the first electrode comprises iridium;
forming a first dielectric layer above the first electrode, wherein the first dielectric layer comprises titanium;
forming a second dielectric layer above the first electrode, wherein the second dielectric layer comprises zirconium; and
forming a second electrode above the first dielectric layer and the second dielectric layer, wherein the second electrode comprises iridium.

17. The method of claim 16, wherein the first dielectric layer comprises titanium oxide.

18. The method of claim 17, wherein the second dielectric layer comprises zirconium oxide.

19. The method of claim 18, wherein the first electrode comprises iridium oxide, and the second dielectric layer is formed above the first electrode and the first dielectric layer.

20. The method of claim 18, wherein the second electrode comprises iridium oxide, and the first dielectric layer is formed above the first electrode and the second dielectric layer.
